(19) United States
(12) Patent Application Publication
(10) Pub. No.: US 2024/0173976 A1
(43) Pub. Date: May 30, 2024

(54) Piezoelectric Element And Piezoelectric Actuator

(71) Applicant: SEIKO EPSON CORPORATION, Tokyo (JP)

(72) Inventors: Tomohiro SAKAI, Matsumoto (JP); Masao NAKAYAMA, Shiojiri (JP); Kazuya KITADA, Matsumoto (JP)

(21) Appl. No.: 18/517,015

(22) Filed: Nov. 22, 2023

(30) Foreign Application Priority Data
Nov. 24, 2022 (JP) 2022-187155

(51) Int. Cl. B41J 2/14; H10N 30/20

(52) U.S. Cl. CPC B41J 2/14233; H10N 30/20

(57) ABSTRACT

A piezoelectric element includes a substrate, a first electrode, a thin-film piezoelectric body containing potassium, sodium, and niobium, and a second electrode. When the thin-film piezoelectric body is divided into two equal parts in a film formation direction, a first electrode side is defined as a first region, and a second electrode side is defined as a second region, a value A obtained by dividing a total value of an XRD peak intensity of a (111) plane and an XRD peak intensity of a (011) plane in the first region by a total value of an XRD peak intensity of a (100) plane, the XRD peak intensity of the (111) plane, and the XRD peak intensity of the (011) plane is smaller than a value B obtained by dividing a total value of an XRD peak intensity of a (111) plane and an XRD peak intensity of a (011) plane in the thin-film piezoelectric body by a total value of an XRD peak intensity of a (100) plane, the XRD peak intensity of the (111) plane, and the XRD peak intensity of the (011) plane.

The present application is based on, and claims priority from JP Application Serial Number 2022-187155, filed Nov. 24, 2022, the disclosure of which is hereby incorporated by reference herein in its entirety.

### BACKGROUND

### 1. Technical Field

The present disclosure relates to a piezoelectric element and a piezoelectric actuator.

### 2. Related Art

In the related art, as one of materials of a piezoelectric layer of a piezoelectric element, potassium sodium niobate (KNN; (K, Na) NbO₃) is proposed (see, for example, JP-A-2016-178253).

The KNN piezoelectric layer made of a KNN film can increase a strain amount by increasing a degree of a crystal orientation of a (100) plane. Therefore, in the development of a piezoelectric element using the KNN piezoelectric layer, the KNN film having a crystal orientation in the (100) plane is generally used. However, the KNN film having the crystal orientation in the (100) plane has a problem that the adhesion strength to an electrode formed on the KNN film is lowered as compared with a KNN film having a crystal orientation in a (111) plane or a (110) plane. Therefore, when a displacement amount of the KNN piezoelectric layer is increased, peeling may occur at an interface between the electrode and the KNN film.

### SUMMARY

According to one aspect of the present disclosure, there is provided a piezoelectric element including: a substrate; a first electrode formed on the substrate; a thin-film piezoelectric body formed on the first electrode and containing potassium, sodium, and niobium; and a second electrode formed on the thin-film piezoelectric body. When the thin-film piezoelectric body is divided into two equal parts in a film formation direction, a first electrode side is defined as a first region, and a second electrode side is defined as a second region, a value A obtained by dividing a total value of an XRD peak intensity of a (111) plane and an XRD peak intensity of a (011) plane in the first region by a total value of an XRD peak intensity of a (100) plane, the XRD peak intensity of the (111) plane, and the XRD peak intensity of the (011) plane is smaller than a value B obtained by dividing a total value of an XRD peak intensity of a (111) plane and an XRD peak intensity a 4 (011) plane in the thin-film piezoelectric body by a total value of an XRD peak intensity of a (100) plane, the XRD peak intensity of the (111) plane, and the XRD peak intensity of the (011) plane.

According to one aspect of the present disclosure, there is provided a piezoelectric actuator including: a vibration plate; a first electrode formed on the vibration plate; a thin-film piezoelectric body formed on the first electrode and containing potassium, sodium, and niobium; and a second electrode formed on the thin-film piezoelectric body. When the thin-film piezoelectric body is divided into two equal parts in a film formation direction, a first electrode side is defined as a first region, and a second electrode side is defined as a second region, a value A obtained by dividing a total value of an XRD peak intensity of a (111) plane and an XRD peak intensity of a (011) plane in the first region by a total value of an XRD peak intensity of a (100) plane, the XRD peak intensity of the (111) plane, and the XRD peak intensity of the (011) plane is smaller than a value B obtained by dividing a total value of an XRD peak intensity of a (111) plane and an XRD peak intensity of a (011) plane in the thin-film piezoelectric body by a total value of an XRD peak intensity of a (100) plane, the XRD peak intensity of the (111) plane, and the XRD peak intensity of the (011) plane.

### BRIEF DESCRIPTION OF THE DRAWINGS

FIG. 1 is a cross-sectional view schematically showing a piezoelectric element 300.

FIG. 2 is a perspective view showing a schematic configuration of an ink jet recording device.

FIG. 3 is an exploded perspective view showing a schematic configuration of an ink jet recording head.

FIG. 4 is a plan view showing a schematic configuration of the ink jet recording head.

FIG. 5 is a cross-sectional view taken along a line A-A′ in FIG. 4, and shows a part of a configuration of a recording head 1.

FIG. 6 shows AFM images of KNN thin film surfaces in Example and Comparative Example.

FIG. 7 shows an XRD measurement result at φ=0° in Example and Comparative Example.

FIG. 8 shows an XRD measurement result at φ=54.74° in Example and Comparative Example.

### DESCRIPTION OF EMBODIMENTS

Hereinafter, embodiments of the present disclosure will be described with reference to the drawings. The following description shows one aspect of the present disclosure, and can be freely modified without departing from the gist of the present disclosure. In the drawings, the same reference signs denote the same members, and description thereof will be appropriately omitted. The numbers following the characters constituting the reference signs are referred to by the reference signs including the same characters, and are used to distinguish elements having the similar configuration. When it is not necessary to distinguish elements indicated by reference signs including the same characters from each other, these elements are referred to by reference signs including only characters.

In each drawing, X, Y, and Z represent three spatial axes perpendicular to one another. In the present specification, the directions along the axes are referred to as a first direction X (X direction), a second direction Y (Y direction), and a third direction Z (Z direction), respectively. A direction of an arrow in the drawings is defined as a positive (+) direction, and a direction opposite to the direction of the arrow is defined as a negative (−) direction. The X direction and the Y direction represent in-plane directions of a plate, a layer, and a film, and the Z direction represents a thickness direction or a lamination direction of the plate, the layer, and the film.

The components shown in the drawings, that is, the shape and size of the parts, the thickness of the plate, the layer, and the film, the relative positional relations, the repeating unit, and the like may be shown in an exaggerated manner for illustrating the present disclosure. The term “on” in the present specification does not limit a positional relation between components to “directly on”. For example, the expressions “a first electrode on a substrate” and “a piezoelectric layer on the first electrode”, which will be described later, do not exclude those including other components between the substrate and the first electrode or between the first electrode and the piezoelectric layer.

### Piezoelectric Element

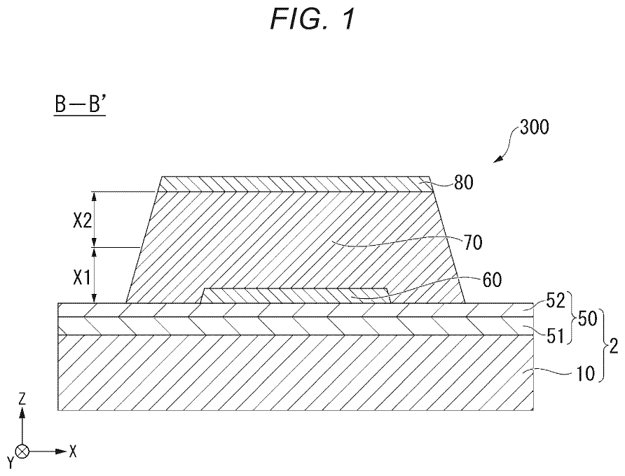

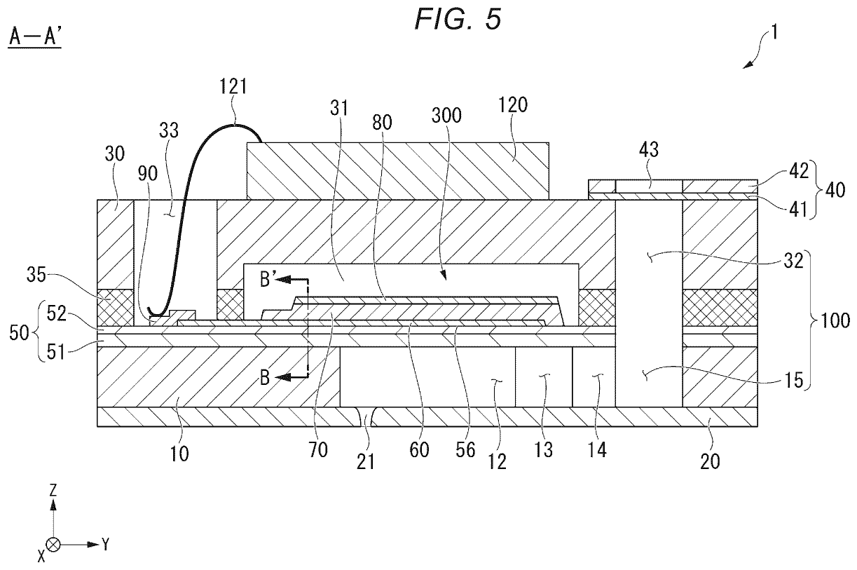

First, a configuration of a piezoelectric element 300 of the present embodiment will be described with reference to the drawings. FIG. 1 is a cross-sectional view schematically showing the piezoelectric element 300, and is an enlarged cross-sectional view taken along a line B-B′ in FIG. 5.

As shown in the drawing, the piezoelectric element 300 includes a substrate 2, a first electrode 60, a piezoelectric layer (thin-film piezoelectric body) 70, and a second electrode 80. The piezoelectric element 300 is provided above the substrate 2. In the shown example, the piezoelectric element 300 is provided on the substrate 2. The thickness of the elements shown in the drawings is merely an example, and can be changed without departing from the gist of the present disclosure.

The substrate 2 is a planar plate formed of, for example, a semiconductor or an insulator. The substrate 2 may be a single layer or a structure that is obtained by laminating a plurality of layers. An internal structure of the substrate 2 is not limited as long as an upper surface has a planar shape, and a structure in which a space or the like is formed may be used.

The substrate 2 includes, for example, a vibration plate 50 that can be deformed by an operation of the piezoelectric layer 70. That is, in the present embodiment, the piezoelectric element 300 is a piezoelectric actuator including the vibration plate 50. In the shown example, the vibration plate 50 includes a silicon oxide layer 51 and an oxide layer 52 provided on the silicon oxide layer 51. In the shown example, the substrate 2 includes a silicon substrate 10, and the vibration plate 50 is provided on the silicon substrate 10.

The silicon oxide layer 51 is a layer containing silicon and oxygen, and is, for example, a silica (SiO₂) layer. The silicon oxide layer 51 may function as an elastic film. The vibration plate 50 may not include the silicon oxide layer 51.

The oxide layer 52 is, for example, a zirconium oxide layer. The oxide layer 52 made of a zirconium oxide (ZrO₂) functions as a diffusion inhibition layer. The oxide layer 52 inhibits metal alkali contained in the piezoelectric layer 70 from diffusing to a silicon substrate 10 side. The oxide layer 52 may contain an oxide other than the zirconium oxide. The oxide layer 52 may also be a layer made of a metal oxide other than the zirconium oxide.

The first electrode 60 is formed on the substrate 2 (the vibration plate 50 in FIG. 1). A shape of the first electrode 60 is, for example, a layered shape or a thin-film shape. A thickness of the first electrode 60 is, for example, 10 nm or more and 200 nm or less. A planar shape of the first electrode 60 as viewed from the Z-axis direction is not particularly limited as long as the piezoelectric layer 70 can be disposed between the second electrode 80 and the first electrode 60 when the second electrode 80 faces the first electrode 60.

Examples of the material of the first electrode 60 include various metals such as nickel, iridium, and platinum, conductive oxides thereof (for example, iridium oxides), complex oxides of strontium and ruthenium (SrRuOₓ:SRO), and complex oxides of lanthanum and nickel (LaNiOₓ:LNO). The first electrode 60 may have a single-layer structure made of the materials illustrated above or a structure obtained by laminating a plurality of the materials.

The first electrode 60 is paired with the second electrode 80, and forms one electrode (for example, a lower electrode formed below the piezoelectric layer 70) for applying a voltage to the piezoelectric layer 70.

The second electrode 80 is formed on the piezoelectric layer 70. The second electrode 80 faces the first electrode 60 with the piezoelectric layer 70 interposed therebetween. A shape of the second electrode 80 is, for example, a layered shape or a thin-film shape. A thickness of the second electrode 80 is, for example, 10 nm or more and 200 nm or less. The planar shape of the second electrode 80 is not particularly limited as long as the piezoelectric layer 70 can be disposed between the first electrode 60 and the second electrode 80 when the second electrode 80 faces the first electrode 60.

As a material of the second electrode 80, for example, the materials listed above as the material of the first electrode 60 can be applied. However, in order for a ratio of the Young's modulus of the piezoelectric layer 70 to the Young's modulus of the second electrode 80 to satisfy the above range, it is preferable to use platinum (Pt) or iridium (Ir) as the material of the second electrode 80.

The second electrode 80 is paired with the first electrode 60, and forms the other electrode (for example, an upper electrode formed above the piezoelectric layer 70) for applying a voltage to the piezoelectric layer 70.

The materials of the first electrode 60 and the second electrode 80 are preferably a noble metal such as platinum (Pt) and iridium (Ir), or an oxide thereof. The material of the first electrode 60 and the material of the second electrode 80 may be materials having conductivity. The material of the first electrode 60 and the material of the second electrode 80 may be the same as or different from each other.

An adhesion layer (not shown) may be provided between the first electrode 60 and the oxide layer 52. The adhesion layer is made of, for example, a titanium oxide (TiOₓ), titanium (Ti), or silicon nitride (SiN), and has a function of improving adhesion between the piezoelectric layer 70 and the vibration plate 50. When a titanium oxide (TiOₓ) layer, a titanium (Ti) layer, or a silicon nitride (SiN) layer is used as the adhesion layer, the adhesion layer also functions as a stopper that prevents potassium and sodium, which are constituent elements of the piezoelectric layer 70, from passing through the first electrode 60 and reaching the silicon substrate 10 when the piezoelectric layer 70 is formed. The adhesion layer may be omitted.

For example, a seed layer (not shown) is preferably provided between the first electrode 60 and the piezoelectric layer 70. The seed layer functions as an orientation control layer that controls orientations of crystals of a piezoelectric body forming the piezoelectric layer 70. That is, by providing the seed layer on the first electrode 60, the crystals of the piezoelectric body constituting the piezoelectric layer 70 can be preferentially oriented in a predetermined plane orientation (for example, (100) plane). Domain rotation can be efficiently utilized and displacement characteristics can be improved by enhancing the crystal orientation of the piezoelectric layer. Examples of a material of the seed layer include various metals such as titanium, nickel, iridium, and platinum, oxides thereof, and compounds containing bismuth, iron, titanium, and lead.

The piezoelectric layer 70 is formed on the first electrode 60 so as to cover the first electrode 60. The piezoelectric layer 70 contains a complex oxide having a perovskite structure represented by a general formula ABO₃. In the present embodiment, the piezoelectric layer 70 contains a piezoelectric material made of a KNN-based complex oxide represented by a formula (Kₓ, Na₁₋ₓ) NbO₃ (0.1≤×≤0.9).

The complex oxide represented by the above formula is a so-called KNN-based complex oxide. The KNN-based complex oxide is a lead-free piezoelectric material in which a content of lead (Pb) or the like is reduced, so that the KNN-based complex oxide is excellent in biocompatibility and has a small environmental burden. In addition, the KNN-based complex oxide has excellent piezoelectric characteristics among the lead-free piezoelectric materials, and thus is advantageous in improving various characteristics.

In the piezoelectric element 300 of the present embodiment, a peak intensity acquired from profile data obtained by X-ray diffraction (XRD) measurement of the piezoelectric layer 70 satisfies the following relation. Each XRD peak intensity is acquired by peak separation of XRD profile data.

When the piezoelectric layer 70 is divided into two equal parts in a film formation direction, and a first electrode 60 side is defined as a first region X1, and a second electrode 80 side is defined as a second region X2, a value A obtained by dividing a total value of an XRD peak intensity I₁(111) of a (111) plane and an XRD peak intensity I₁(110) of the (110) plane in the first region X1 by a total value of an XRD peak intensity I₁(100) of a (100) plane, the XRD peak intensity I₁(111) of the (111) plane, and the XRD peak intensity I₁(110) of the (110) plane is smaller than a value B obtained by dividing a total value of an XRD peak intensity I₀(111) of a (111) plane and an XRD peak intensity I₀(110) of a (110) plane in the piezoelectric layer 70 by a total value of an XRD peak intensity I₀(100) of a (100) plane, the XRD peak intensity I₀(111) of the (111) plane, and the XRD peak intensity I₀(110) of the (110) plane.

That is, the value A of the first region X1 and the value B of the entire piezoelectric layer 70 satisfy the following relational expression.

A={I₁(111)+I₁(110)}/{I₁(100)+I₁(111)+I₁(110)}[ Formula 1]

Value B={I₀(111)+I₀(110)}/{I₀(100)+I₀(111)+I₀(110)} [Formula 2]

A<B [Formula 3]

In the piezoelectric element 300 of the present embodiment, a proportion of KNN crystals oriented in the (111) plane or the (110) plane in the first region X1 on the lower layer side is larger than a proportion of the KNN crystals oriented in the (111) plane or the (110) plane in the entire piezoelectric layer 70. That is, in the second region X2 that is a portion of the piezoelectric layer 70 on the second electrode 80 side, a proportion of the KNN crystals oriented in the (111) plane or the (110) plane is larger than that of the KNN crystals oriented in the (111) plane or the (110) plane in the first region X1.

With this configuration, the adhesion between the second region X2 of the piezoelectric layer 70 and the second electrode 80 can be improved. As will be described in detail in Example to be described later, the arithmetic average height (surface roughness) of a surface of the KNN film varies depending on the orientation of crystal grains positioned on a film surface. Specifically, the KNN crystals oriented in the (111) plane or the (110) plane have a surface unevenness height larger than that of the KNN crystals oriented in the (100) plane. Accordingly, a surface of the second region X2 containing a large amount of KNN crystals oriented in the (111) plane or the (110) plane has a larger arithmetic average height than a surface of the film containing a small amount of KNN crystals oriented in the (111) plane or the (110) plane.

The second electrode 80 is formed on the surface of the second region X2 having a large arithmetic average height, and thus the second electrode 80 strongly adheres to a surface of the piezoelectric layer 70 by an anchor effect generated by the unevenness of the surface. Accordingly, even when the displacement amount of the piezoelectric layer 70 is increased, the film is less likely to peel off at the interface between the piezoelectric layer 70 and the second electrode 80.

In the present embodiment, the arithmetic average height (Sa) of the piezoelectric layer 70 at the interface with the second electrode 80 is preferably 0.0032 nm or more and 0.0080 nm or less. When the arithmetic average height (surface roughness) of the piezoelectric layer 70 is set in the above range, good adhesion is obtained at the interface between the piezoelectric layer 70 and the second electrode 80. When the arithmetic average height (Sa) is less than 0.0022 nm, the adhesion between the piezoelectric layer 70 and the second electrode 80 may be insufficient. When the arithmetic average height exceeds 0.020 nm, the variation the thickness of the in piezoelectric layer 70 is large. Therefore, the variation in the piezoelectric characteristics of the piezoelectric element 300 is likely to be large, and cracks are likely to occur in the piezoelectric layer 70.

Further, in the first region X1 on the lower layer side of the piezoelectric layer 70 of the present embodiment, the proportion of the KNN crystals oriented in the (111) plane or the (110) plane is small, and the proportion of the KNN crystals oriented in the (100) plane is large. When the KNN crystals are oriented in the (100) plane, good piezoelectric characteristics can be easily obtained for the KNN piezoelectric body.

According to the present embodiment, good piezoelectric characteristics are obtained in the first region X1 of the piezoelectric layer 70, and good adhesion to the second electrode 80 is obtained in the second region X2 of the piezoelectric layer 70. Even if the displacement amount of the piezoelectric layer 70 is increased, film peeling at the thin film interface can be prevented. According to the present embodiment, the piezoelectric element 300 having both piezoelectric characteristics and durability can be obtained.

The value B of the entire piezoelectric layer 70 is preferably four times or more the value A of the first region X1. With this configuration, the difference in the proportions of the KNN crystals oriented in the (111) plane and the (110) plane between the first region X1 and the second region X2 can be increased. In the first region X1, the proportion of the KNN crystals oriented in the (100) plane and having excellent piezoelectric characteristics can be increased, and in the second region X2, the proportion of the KNN crystals oriented in the (111) plane or the (110) plane and having excellent adhesion can be increased. Piezoelectric characteristics and durability of the piezoelectric element 300 can be further improved.

The arithmetic average height and the crystal orientation of the piezoelectric layer 70 in the piezoelectric element 300 can be measured by the following method.

(1) The piezoelectric element 300 is wet-etched with aqua regia to remove the second electrode 80 made of, for example, platinum. The KNN film of the piezoelectric layer 70 is hardly etched with aqua regia, and thus the KNN film can be exposed while substantially maintaining the surface state during film formation.

(2) The surface of the exposed piezoelectric layer 70 (KNN film) is measured by atomic force microscopy (AFM) to calculate an arithmetic average height (Sa). The piezoelectric layer 70 is measured by XRD to calculate the crystal orientation.

(3) After performing wet etching with an etching solution, ion milling is performed with argon to partially remove the piezoelectric layer 70 from above. When the thickness is about half, the ion milling is stopped.

(4) The surface of the KNN film whose thickness is halved is measured by XRD to calculate the crystal orientation.

Although the piezoelectric element 300 is described above, the piezoelectric material forming the piezoelectric layer 70 is not limited to the composition represented by the above formula (1) as long as the piezoelectric material is a KNN-based complex oxide. For example, another metal element (additive) may be contained in an A site or a B site of potassium sodium niobate. Examples of such additives include manganese (Mn), lithium (Li), barium (Ba), calcium (Ca), strontium (Sr), zirconium (Zr), titanium (Ti), bismuth (Bi), tantalum (Ta), antimony (Sb), iron (Fe), cobalt (Co), silver (Ag), magnesium (Mg), zinc (Zn), and copper (Cu). One or more of these additives may be contained. When the additive is used, various characteristics are improved and diversification of the configuration and function is easily achieved. In the case of a complex oxide containing other elements, it is preferable that the complex oxide also has an ABO₃ perovskite structure.

In the present specification, the “perovskite complex oxide containing K, Na, and Nb” is a “complex oxide having an ABO₃ perovskite structure and containing K, Na, and Nb”, and is not limited to only a complex oxide having an ABO₃ perovskite structure and containing K, Na, and Nb. That is, in the present specification, the “perovskite complex oxide containing K, Na, and Nb” contains a piezoelectric material represented as a mixed crystal containing a complex an ABO₃ perovskite structure and containing K, Na, and Nb (for example, the KNN-based complex oxide illustrated above) and another complex oxide having an ABO₃ perovskite structure.

The other complex oxide is not limited within the scope of the present embodiment, and is preferably a lead-free piezoelectric material containing no lead (Pb). According to this, the piezoelectric element 300 is excellent in biocompatibility and has a small environmental burden.

### Method for Producing Piezoelectric Element

Next, an example of a method for producing the piezoelectric element 300 (piezoelectric actuator) shown in FIG. 1 will be described. A case where the piezoelectric layer 70 is produced by a chemical solution method (wet method) is described below, and the production method of the piezoelectric layer 70 is not limited to the wet method and may be a vapor phase method.

First, the silicon substrate 10 is prepared, and the silicon substrate 10 is thermally oxidized to form, on a surface of the silicon substrate 10, the silicon oxide layer 51 made of silicon dioxide (SiO₂).

Next, the oxide layer 52 made of aluminum oxide (Al₂O₃) or tantalum oxide (Ta₂O₅) is formed on the silicon oxide layer 51 by atomic layer deposition (ALD). The film formation temperature is, for example, 250° C. to 350° C. The oxide layer 52 can be formed by a sputtering method, a vapor deposition method, or the like in addition to ALD. For example, first, an aluminum film or a tantalum film is formed on the silicon oxide layer 51 by a sputtering method or a vapor deposition method, and the aluminum film or the tantalum film is thermally oxidized to obtain the oxide layer 52 made of aluminum oxide (Al₂O₃) or tantalum oxide (Ta₂O₅). In this manner, the vibration plate 50 including the silicon oxide layer 51 and the oxide layer 52 is formed on the silicon substrate 10.

Next, an adhesion layer made of metallic titanium (Ti) is formed on the oxide layer 52. The adhesion layer can be formed by the sputtering method or the like. Next, the first electrode 60 made of platinum (Pt) is formed on the adhesion layer. The first electrode 60 can be appropriately selected according to an electrode material, and can be formed by vapor phase film formation such as a sputtering method, a vacuum vapor deposition method (PVD method), and a laser ablation method, or liquid phase film formation such as a spin coating method.

Next, the seed layer (orientation control layer) which is not shown is formed on the first electrode 60. The seed layer can be formed by, for example, a chemical solution method (wet method) in which a solution containing a metal complex (precursor solution) is coated and dried, and then sintered at a high temperature to obtain a metal oxide. Examples of the material of the seed layer include various metals such as titanium, nickel, iridium, and platinum, and oxides thereof.

Next, a resist having a predetermined shape is formed on the first electrode 60 as a mask, and the adhesion layer, the first electrode 60, and the seed layer are simultaneously patterned. Patterning of the adhesion layer, the first electrode 60, and the seed layer can be performed by dry etching such as reactive ion etching (RIE) and ion milling, or wet etching using an etchant. The shapes in the patterning of the adhesion layer, the first electrode 60, and the seed layer are not particularly limited.

Next, a plurality of piezoelectric films are formed on the first electrode 60.

The piezoelectric layer 70 is formed of the plurality of piezoelectric films. The piezoelectric layer 70 can be formed by, for example, a chemical solution method (wet method) in which a solution containing a metal complex (precursor solution) is coated and dried, and then sintered at a high temperature to obtain a metal oxide. Other methods such as a laser ablation method, a sputtering method, a pulsed laser deposition method (PLD method), a chemical vapor deposition method (CVD method), and an aerosol deposition method may also be used.

Here, the wet method (liquid phase method) is a method for forming a film by a chemical solution method such as an MOD method or a sol-gel method, and is a concept distinguished from the vapor phase method such as a sputtering method. In the present embodiment, a vapor phase method may be used as long as the piezoelectric layer 70 containing aluminum oxide and/or tantalum oxide can be formed.

For example, the piezoelectric layer 70 formed by the wet method (liquid phase method) includes a plurality of piezoelectric films formed by a series of steps including a step of performing coating with a precursor solution to form a precursor film (coating step), a step of drying the precursor film (drying step), a of heating and degreasing the dried precursor film (degreasing step), and a step of sintering the degreased precursor film (sintering step). That is, the piezoelectric layer 70 is formed by repeating a series of steps from the coating step to the sintering step a plurality of times. In the series of steps described above, the sintering step may be performed after repeating the coating step to the degreasing step a plurality of times.

A specific procedure when the piezoelectric layer 70 is formed by the wet method (liquid phase method) is, for example, as follows.

First, a precursor solution containing a predetermined metal complex is prepared. The precursor solution is obtained by dissolving or dispersing, in an organic solvent, a metal complex capable of forming a complex oxide containing K, Na, and Nb by sintering. At this time, a metal complex containing an additive such as Mn, Li, and Cu may be further mixed. An insulation property of the piezoelectric layer 70 to be obtained can be further enhanced by mixing the metal complex containing Mn, Li, or Cu with the precursor solution.

Examples of a metal complex containing potassium (K) include potassium 2-ethylhexanoate and potassium acetate. Examples of a metal complex containing sodium (Na) include sodium 2-ethylhexanoate and sodium acetate. Examples of a metal complex containing niobium (Nb) include niobium 2-ethylhexanoate and pentaethoxyniobium. When Mn is added as an additive, examples of a metal complex containing Mn include manganese 2-ethylhexanoate. When Li is added as an additive, examples of a metal complex containing Li include lithium 2-ethylhexanoate. At this time, two or more metal complexes may be used in combination. For example, potassium 2-ethylhexanoate and potassium acetate may be used in combination as the metal complex containing potassium (K). Examples of the solvent include 2-n-butoxyethanol, n-octane, and a mixed solvent thereof. The precursor solution may contain an additive that stabilizes the dispersion of the metal complex containing K, Na, or Nb. Examples of such an additive include 2-ethylhexanoic acid.

Then, the silicon substrate 10 on which the silicon oxide layer 51, the oxide layer 52, and the first electrode 60 are formed is coated with the above precursor solution to form a precursor film (coating step).

Next, the precursor film is heated to a predetermined temperature, for example, about 130° C. to 250° C. and dried for a certain period of time (drying step).

Next, the dried precursor film is heated to a predetermined temperature, for example, 250° C. to 450° C., and is held at the temperature for a certain period of time to perform degreasing (degreasing step).

Next, the precursor film after degreasing is sintered by being heated to a predetermined temperature, for example, 750° C. to 850° C. and being held at the temperature for 3 minutes to 7 minutes, and a piezoelectric film is formed (sintering step).

Examples of a heating device used in the drying step, the degreasing step, and the sintering step include a rapid thermal annealing (RTA) device that perform heating by irradiation with an infrared ray lamp, and a hot plate. The above steps are repeated a plurality of times to form the piezoelectric layer 70 made of a plurality of piezoelectric films. In a series of steps from the coating step to the sintering step, the sintering step may be performed after repeating the steps from the coating step to the degreasing step a plurality of times.

In the piezoelectric layer 70 of the present embodiment, the distributions of the micro crystal orientation of the KNN crystals are different between the first region X1 and the second region X2 as described above. The piezoelectric layer 70 can be produced, for example, by controlling the thickness per layer of the piezoelectric film to be laminated. Regarding the KNN film formed by the liquid phase method, the thickness per layer of the piezoelectric film after sintering can be controlled by adjusting the coating conditions. When the thickness per layer of the piezoelectric film is reduced, the proportion of the KNN crystals oriented in the (100) plane increases, and when the thickness per layer of the piezoelectric film is increased, the ratio of the KNN crystals oriented in the (011) plane or the (111) plane increases. The distributions of the crystal orientation of the KNN crystals can be different between the lower layer side (the first electrode 60 side) and the upper layer side (the second electrode 80 side) of the piezoelectric layer 70 by utilizing the thickness per layer of the piezoelectric film.

That is, in the step of forming the piezoelectric layer 70, an average thickness per layer of the piezoelectric film in the step of forming a portion to be the first region X1 of the piezoelectric layer 70 is smaller than an average thickness per layer of the piezoelectric film in the step of forming a portion to be the second region X2 of the piezoelectric layer 70. Accordingly, the piezoelectric layer 70 having different distributions of crystal orientations in the first region X1 and the second region X2 can be formed.

In the two kinds of piezoelectric films having different thicknesses per layer, the piezoelectric film containing a large number of KNN crystals oriented in the (011) plane or the (111) plane is preferably positioned in an outermost layer of the piezoelectric layer 70 even in the second region X2. Accordingly, a desired arithmetic average height (surface roughness) is easily obtained on the surface of the piezoelectric layer 70 to be the interface with the second electrode 80. In addition, the piezoelectric film containing a large number of KNN crystals oriented in the (011) plane or the (111) plane is inferior in the piezoelectric characteristics than the piezoelectric film containing a large number of KNN crystals oriented in the (100) plane. The lower layer side relative to the outermost layer can be formed by the piezoelectric film containing a large number of KNN crystals oriented in the (100) plane by disposing the piezoelectric film containing a large number of KNN crystals oriented in the (011) plane or the (111) plane at the outermost layer of the piezoelectric film 70. Therefore, the piezoelectric characteristics of the entire piezoelectric layer 70 can be easily enhanced.

The piezoelectric film containing a large number of KNN crystals oriented in the (011) plane or the (111) plane is a film that imparts unevenness to the surface of the piezoelectric layer 70 and improves the adhesion to the second electrode 80, so that it is preferable to form the piezoelectric film as thin as possible within a range in which good adhesion between the piezoelectric film 70 and the second electrode 80 is obtained. For example, the thickness of the piezoelectric film containing a large number of KNN crystals oriented in the (011) plane or the (111) plane may be in the range of 5% to 15% of the thickness of the entire piezoelectric layer 70. The proportion of the piezoelectric film containing a large number of KNN crystals oriented in the (100) plane can be increased, and the piezoelectric characteristics of the piezoelectric layer 70 can be enhanced.

In addition, before and after forming the second electrode 80 on the piezoelectric layer 70, a reheating treatment (post-annealing) may be performed in a temperature range of 600° C. to 800° C. if necessary. When performing the post-annealing in this manner, a good interface between the piezoelectric layer 70 and the first electrode 60 and a good interface between the piezoelectric layer 70 and the second electrode 80 can be formed. In addition, the crystallinity of the piezoelectric layer 70 can be improved, and the insulation property of the piezoelectric layer 70 can be further enhanced.

After the sintering step, the piezoelectric layer 70 made of a plurality of piezoelectric films is patterned into a desired shape. The patterning can be performed by dry etching such as reactive ion etching or ion milling, or wet etching using an etchant.

Thereafter, the second electrode 80 is formed on the piezoelectric layer 70. The second electrode 80 can be formed by the same method as the first electrode 60.

Through the above steps, the piezoelectric element 300 including the first electrode 60, the piezoelectric layer 70, and the second electrode 80 is produced.

### Piezoelectric Element Applied Device

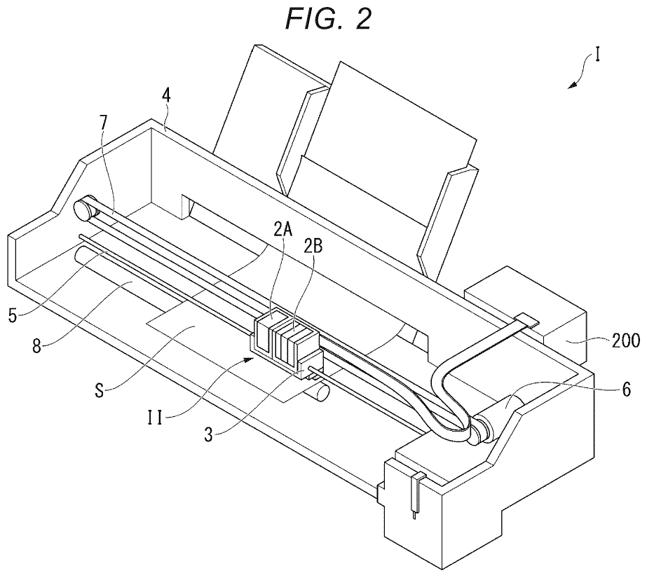

Next, an ink jet recording device as an example of a liquid ejecting device including a recording head, which is an example of a piezoelectric element applied device according to the present embodiment, will be described with reference to the drawings. FIG. 2 is a perspective view showing a schematic configuration of the ink jet recording device.

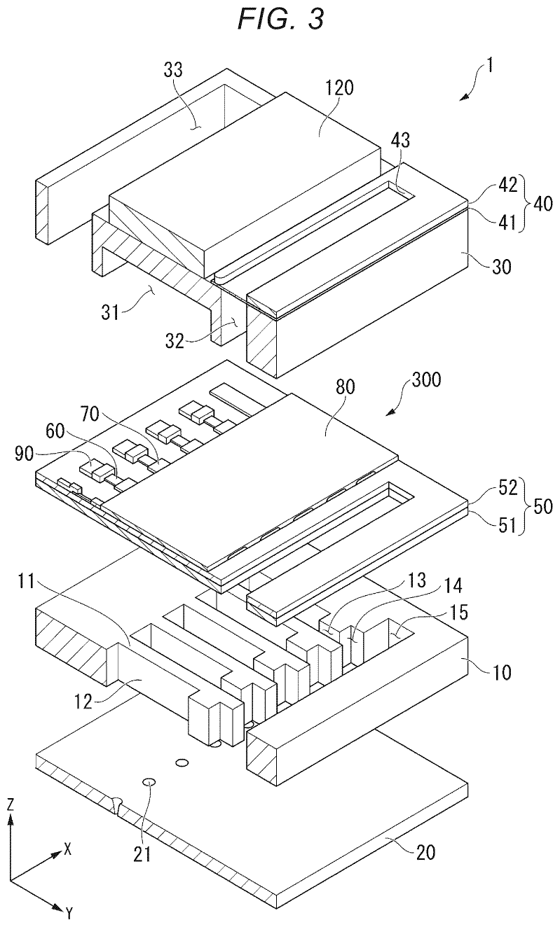

In an ink jet recording device (recording device) I as shown in FIG. 2, an ink jet recording head unit (head unit) II is detachably attached to cartridges 2A and 2B. The cartridges 2A and 2B form an ink supply unit. The head unit II includes a plurality of ink jet recording heads (recording heads) 1 (see FIG. 3 and the like), and is mounted on a carriage 3. The carriage 3 is provided on a carriage shaft 5 attached to a device body 4 in a manner of being movable in an axial direction. The head unit II and the carriage 3 can discharge, for example, a black ink composition and a color ink composition separately.

A driving force from a drive motor 6 is transmitted to the carriage 3 via a plurality of gears (not shown) and a timing belt 7, and the carriage 3 on which the head unit II is mounted is moved along the carriage shaft 5. On the other hand, the device body 4 is provided with a conveyance roller 8 as a conveyance unit, and a recording sheet S that is a recording medium (medium) such as paper is conveyed by the conveyance roller 8. The conveyance unit that conveys the recording sheet S is not limited to the conveyance roller, and may be a belt, a drum, or the like.

In the recording head (head chip) 1, the piezoelectric element 300 (see FIG. 1) is used as a piezoelectric actuator device. Deterioration in various characteristics (piezoelectric characteristics, durability, ink ejection characteristics, and the like) of the recording device 1 can be prevented by using the piezoelectric element 300. The piezoelectric element applied device of the present embodiment can particularly improve the piezoelectric characteristics and durability by applying the piezoelectric element 300.

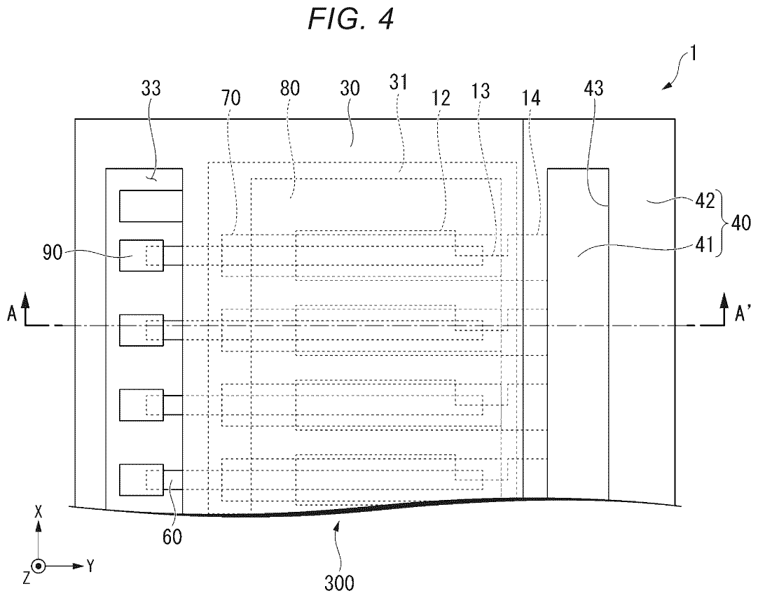

Next, the recording head (head chip) 1 as an example of a head chip mounted on a liquid ejecting device will be described with reference to the drawings. FIG. 3 is an exploded perspective view showing a schematic configuration of the ink jet recording head. FIG. 4 is a plan view showing a schematic configuration of an ink jet recording head. FIG. 5 is a cross-sectional view taken along a line A-A′ in FIG. 4. FIGS. 3 to 5 show a part of the configuration of the recording head 1, and the configuration is appropriately omitted.

As shown in FIG. 3, the recording head (head chip) 1 includes a nozzle plate 20 including nozzle openings 21 for ejecting liquid droplets, pressure generation chambers 12 communicating with the nozzle openings 21, partition walls 11 provided on the nozzle plate 20 and forming the pressure generation chambers 12, a flow path forming substrate (silicon substrate) 10 forming a part of wall surfaces of the pressure generation chambers 12, the piezoelectric element 300 provided on the silicon substrate 10, and lead electrodes (voltage application units) 90 for applying a voltage to the piezoelectric element 300.

A plurality of partition walls 11 are formed on the silicon substrate 10. A plurality of pressure generation chambers 12 are divided by the partition walls 11. That is, the pressure generation chambers 12 are arranged side by side along the X direction (the direction in which the nozzle openings 21 for ejecting ink of the same color are arranged side by side) on the silicon substrate 10. With such a configuration, a movable portion of the piezoelectric element 300 is formed. As the silicon substrate 10, for example, a silicon single crystal substrate can be used.

On the silicon substrate 10, an ink supply path 13 and a communication path 14 are formed on one end portion side (+Y direction side) of the pressure generation chamber 12. The ink supply path 13 is configured such that an area of an opening on one end portion side of the pressure generation chamber 12 is small. The communication path 14 has substantially the same width as the pressure generation chamber 12 in the +X direction. A communication portion 15 is formed on an outer side (+Y direction side) of the communication path 14. The communication portion 15 forms a part of a manifold 100. The manifold 100 serves as an ink chamber common to the pressure generation chambers 12. In this manner, a liquid flow path including the pressure generation chamber 12, the ink supply path 13, the communication path 14, and the communication portion 15 is formed on the silicon substrate 10.

The nozzle plate 20 made of, for example, SUS is bonded to one surface (a surface on a −Z direction side) of the silicon substrate 10. In the nozzle plate 20, the nozzle openings 21 are arranged side by side along the +X direction. The nozzle opening 21 communicates with each of the pressure generation chambers 12. The nozzle plate 20 can be bonded to the silicon substrate 10 by an adhesive, a thermal welding film, or the like.

The vibration plate 50 is formed on the other surface (a surface on a +Z direction side) of the silicon substrate 10. The vibration plate 50 includes, for example, the silicon oxide layer 51 formed on the silicon substrate 10 and the oxide layer 52 formed on the silicon oxide layer 51. The silicon oxide layer 51 is made of, for example, silicon dioxide (SiO₂), and the oxide layer 52 is made of, for example, aluminum oxide (Al₂O₃) or tantalum oxide (Ta₂O₅). The silicon oxide layer 51 may not be a member separate from the silicon substrate 10. A part of the silicon substrate 10 may be thinned and used as the silicon oxide layer 51. The oxide layer 52 functions as a stopper for preventing potassium and sodium which are constituent elements of the piezoelectric layer 70 from passing through the first electrode 60 and reaching the silicon substrate 10 when forming the piezoelectric layer 70 described later.

The first electrode 60 is provided for each pressure generation chamber 12. That is, the first electrode 60 is formed as an individual electrode independent for each pressure generation chamber 12. The first electrode 60 is formed to be smaller than a width of the pressure generation chamber 12 in the ±X directions. The first electrode 60 is formed to be wider than a length of the pressure generation chamber 12 in the ±Y directions. That is, in the ±Y directions, both end portions of the first electrode 60 are formed to an outer side of a region facing the pressure generation chamber 12 on the vibration plate 50. The lead electrode (voltage application unit) 90 for applying a voltage to the piezoelectric element 300 is connected to one end portion side (a side opposite to the communication path 14) of the first electrode 60.

The piezoelectric layer 70 is provided between the first electrode 60 and the second electrode 80. The piezoelectric layer 70 is a thin-film piezoelectric body. The piezoelectric layer 70 is formed with a width larger than the width of the first electrode 60 in the ±X directions. The piezoelectric layer 70 is formed with a length larger than the length of the pressure generation chamber 12 in the ±Y directions. An end portion of the piezoelectric layer 70 on an ink supply path 13 side (+Y direction side) is formed up to an outer side relative to an end portion of the first electrode 60 on the +Y direction side. That is, the end portion of the first electrode 60 on the +Y direction side is covered with the piezoelectric layer 70. On the other hand, an end portion of the piezoelectric layer 70 on a lead electrode 90 side (−Y direction side) is located inward (on the +Y direction side) from an end portion of the first electrode 60 on the −Y direction side. That is, the end portion of the first electrode 60 on the −Y direction side is not covered with the piezoelectric layer 70.

The second electrode 80 is provided continuously on the piezoelectric layer 70 and the vibration plate 50 over the +X direction. That is, the second electrode 80 is formed as a common electrode common to a plurality of the piezoelectric layers 70. In the present embodiment, the first electrode 60 forms an individual electrode that is provided independently corresponding to the pressure generation chamber 12, and the second electrode 80 forms a common electrode that is provided continuously in an arrangement direction of the pressure generation chambers 12. Alternatively, the first electrode 60 may form a common electrode, and the second electrode 80 may form an individual electrode.

In the present embodiment, the vibration plate 50 and the first electrode 60 are displaced by displacement of the piezoelectric layer 70 having electromechanical conversion characteristics. That is, the vibration plate 50 and the first electrode 60 substantially function as a vibration plate. However, in practice, the second electrode 80 is also displaced by the displacement of the piezoelectric layer 70, and thus a region on which the vibration plate 50, the first electrode 60, the piezoelectric layer 70, and the second electrode 80 are sequentially laminated functions as a movable portion (also referred to as a vibration portion) of the piezoelectric element 300.

A protective substrate 30 is bonded by an adhesive 35 onto the silicon substrate 10 (vibration plate 50) on which the piezoelectric element 300 is formed. The protective substrate 30 includes a manifold portion 32. The manifold portion 32 forms at least a part of the manifold 100. The manifold portion 32 of the present embodiment penetrates the protective substrate 30 in the thickness direction (Z direction), and is formed over the width direction (+X direction) of the pressure generation chambers 12. The manifold portion 32 communicates with the communication portion 15 of the silicon substrate 10. With these configurations, the manifold 100 serving as an ink chamber common to the pressure generation chambers 12 is formed.

In the protective substrate 30, a piezoelectric element holding portion 31 is formed in a region including the piezoelectric element 300. The piezoelectric element holding portion 31 has a space that does not hinder a movement of the piezoelectric element 300. The space may or may not be closed. The protective substrate 30 is provided with a through hole 33 penetrating the protective substrate 30 in the thickness direction (Z direction). An end portion of the lead electrode 90 is exposed from the through hole 33.

Examples of a material of the protective substrate 30 include Si, SOI, glass, a ceramic material, a metal, and a resin. It is more preferable that the protective substrate 30 is formed of a material having substantially the same thermal expansion rate as the silicon substrate 10.

A drive circuit 120 functioning as a signal processing unit is fixed onto the protective substrate 30. As the drive circuit 120, for example, a circuit board or a semiconductor integrated circuit (IC) can be used. The drive circuit 120 is electrically coupled to the lead electrodes 90 via connection wiring 121 made of a conductive wire such as a bonding wire inserted through the through hole 33. The drive circuit 120 can be electrically coupled to a printer controller 200 (see FIG. 2). The drive circuit 120 functions as a control unit of the piezoelectric actuator device (piezoelectric element 300).

A compliance substrate 40 including a sealing film 41 and a fixing plate 42 is bonded onto the protective substrate 30. The sealing film 41 may be made of a material having a low rigidity, and the fixing plate 42 may be made of a hard material such as a metal. A region of the fixing plate 42 facing the manifold 100 serves as an opening 43 obtained by completely removing the fixing plate 42 in the region in the thickness direction (Z direction). One surface (surface on the +Z direction side) of the manifold 100 is sealed only by the sealing film 41 having flexibility.

The recording head 1 ejects ink droplets by the following operation.

First, ink is introduced from an ink introduction port coupled to an external ink supply unit (not shown), and the inside from the manifold 100 to the nozzle opening 21 is filled with the ink. Thereafter, in accordance with recording signals from the drive circuit 120, a voltage is applied between the first electrode 60 and the second electrode 80 corresponding to each of the pressure generation chambers 12, and the piezoelectric element 300 is bent and deformed. Accordingly, the pressure in each pressure generation chamber 12 is increased, and ink droplets are ejected from the nozzle opening 21.

In the above embodiment, the ink jet recording head is described as an example of a liquid ejecting head, but the present disclosure can be applied to general liquid ejecting heads, and can also be applied to a liquid ejecting head that ejects a liquid other than ink. Examples of other liquid ejecting heads include various recording heads used in an image recording device such as a printer, a color material ejecting head used for producing a color filter such as a liquid crystal display, an electrode material ejecting head used for forming electrodes such as an organic EL display and a field emission display (FED), and a bioorganic material ejecting head used for producing a biochip.

In addition, the present disclosure is not limited to the piezoelectric element mounted on the liquid ejecting head, and can also be applied to a piezoelectric element mounted on another piezoelectric element applied device. Examples of the piezoelectric element applied device include an ultrasonic device, a motor, a pressure sensor, a pyroelectric element, and a ferroelectric element. The piezoelectric element applied device also includes a finished product using the piezoelectric element applied device, for example, a liquid ejecting device using the above liquid ejecting head, an ultrasonic sensor using the above ultrasonic device, a robot using the above motor as a drive source, an IR sensor using the above pyroelectric element, and a ferroelectric memory using a ferroelectric element.

In particular, the piezoelectric element of the present disclosure is preferable as a piezoelectric element mounted on a sensor. Examples of the sensor include a gyro sensor, an ultrasonic sensor, a pressure sensor, and a speed and acceleration sensor. When the piezoelectric element of the present disclosure is applied to a sensor, for example, a voltage detection unit that detects a voltage output from the piezoelectric element 300 may be provided between the first electrode 60 and the second electrode 80 to form a sensor. In the case of such a sensor, when the piezoelectric element 300 is deformed due to an external change (change in a physical quantity), a voltage is generated along with the deformation. Various physical quantities can be detected by detecting the voltage by the voltage detection unit.

### Example

Hereinafter, the present disclosure will be described in more detail with reference to Example, but the present disclosure is not limited to Example.

### Example

### Solution Preparation

Potassium acetate and 2-ethylhexanoic acid were mixed and stirred under heating. Thereafter, the above mixed solution was cooled to room temperature, and n-octane was added to prepare a potassium 2-ethylhexanoate solution. Similarly, sodium acetate, niobium ethoxide, calcium acetate, and manganese acetate were used to prepare a sodium 2-ethylhexanoate solution, a niobium 2-ethylhexanoate solution, a calcium 2-ethylhexanoate solution, and a manganese 2-ethylhexanoate solution, respectively. For each of the above prepared solutions, a concentration of each solution was measured by performing inductively coupled plasma emission (ICP) analysis. In the precursor solution preparation step described later, a precursor solution containing potassium, sodium, niobium, and manganese was prepared based on the above measured concentrations.

### Substrate Production

First, a surface of a silicon substrate (6 inches) serving as a substrate was thermally oxidized to form a silicon oxide layer made of a silicon dioxide film having a thickness of 1080 nm on the substrate. Further, a zirconium oxide film having a thickness of 400 nm was formed on the silicon oxide layer by a DL sputtering method. Next, a platinum film having a thickness of 50 nm was formed as a lower electrode (first electrode) by sputtering.

### Preparation of Precursor Solution

A sodium 2-ethylhexanoate solution, a niobium 2-ethylhexanoate solution, a calcium 2-ethylhexanoate solution, and a manganese 2-ethylhexanoate solution were mixed at the following component ratios (atomic ratios) to prepare a KNNM precursor solution 1 and a KNNM precursor solution 2.
KNNM Precursor Solution 1: K:Na:Nb:Mn=40:60:199:1
KNNM Precursor Solution 2:K:Na:Nb:Mn=103:103:199:1

### Piezoelectric Layer Formation

### Example

Next, a piezoelectric layer was formed on the lower electrode by the following procedures.

The lower electrode was coated with the KNNM precursor solution 1 by spin coating to form a precursor film 1. Next, the precursor film 1 was dried by being heated to 180° C. on a hot plate (drying step), and then degreased by being heated to 380° C. (degreasing step). Next, the degreased precursor film was subjected to a heat treatment at 750° C. using rapid thermal annealing (RTA) to form a KNNM thin film having a thickness of 75 nm (sintering step).

Next, a KNNM thin film 2 having a thickness of 38 nm was formed on the above KNNM thin film by the same process except that the coating solution was changed to the KNNM precursor solution 2. The step of forming the KNNM thin film 2 was performed 16 times. Thereafter, the KNNM thin film 2 having a thickness of 42 nm was produced by changing spin coating conditions during the production of the KNNM thin film 2. A KNN thin film having a thickness of about 767 nm was produced by performing the step of forming the KNNM thin film 2 twice.

In this example, crystal structure analysis was performed in the middle of and after the formation of the KNN thin film. The crystal structure analysis was performed twice on a surface of the KNN thin film having a thickness of 417 nm after the formation of the KNNM thin film 2 was performed nine times and on a surface of the KNN thin film having a thickness of 767 nm after the formation of the KNNM thin film 2 was performed 18 times.

After the formation of the KNN thin film, surface analysis of the KNN thin film surface was performed.

Further, after a surface shape was measured, a 50 nm Pt film was formed by sputtering to form a second electrode, and a piezoelectric element was obtained. Thereafter, a tape was attached to a surface of the Pt film, and an adhesive force between the KNN thin film and the Pt film was evaluated.

### Comparative Example

A KNN thin film was produced and evaluated by the same process as Example except that a thickness per layer was changed to 38 nm by changing the spin coating conditions during production of the KNNM thin film 2, and the film forming step was performed 20 times to produce a KNN thin film having a thickness of about 815 nm.

### KNN Surface Analysis

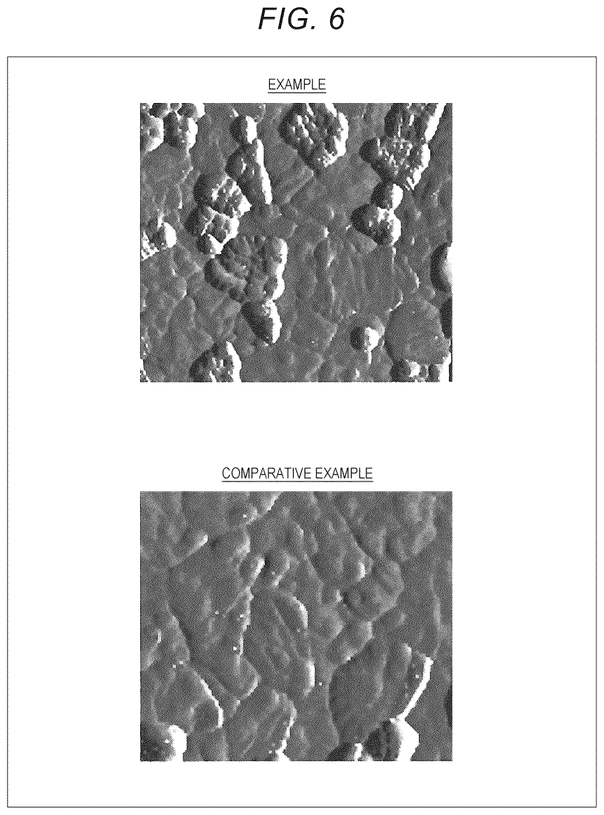

After the KNN thin film was produced, surfaces of the KNN thin films in Example and Comparative Example were measured by the AFM. The measurement results are shown in FIG. 6. As shown in FIG. 6, a planar region and a region having large unevenness were mixed on the surface of the KNN thin film in Example. As a result of evaluating the surface of the KNN thin film by electron backscatter diffraction (EBSD) method, it was found that KNN crystals in the planar region were oriented in the (100) plane, and KNN crystals in the region having large unevenness were oriented in the (111) plane.

On the other hand, it was found that a ratio of the planar region in the surface of the KNN thin film in Comparative Example than that of the surface of the KNN thin film in Example.

### Structure Analysis

The crystal structure and orientation of the KNN thin film in Example were analyzed by measuring two-dimensional mapping images and diffraction patterns at φ=0° and 54.74° using an X-ray diffraction device “D8 Discover” (radiation source: CuKα, two-dimensional detector GADDS) manufactured by Bruker AXS. In the measurement at φ=0°, the substrate is irradiated with X-rays at an angle of 90°. That is, the measurement at φ=0° is the same measurement method as a general XRD measurement. When the KNN thin film is regarded as a pseudo-cubic crystal and XRD is measured at φ=0°, a strong diffraction peak derived from the (100) plane is observed in a vicinity of 2θ=21° to 24° in the (100) oriented KNN thin film. Hereinafter, unless otherwise noted, the structure of KNN is treated as a pseudo-cubic crystal. However, this is an expression for simplifying the description, and the expression does not deny that KNN in the present specification has a crystal structure with low symmetry, such as a tetragonal crystal and an orthorhombic crystal. In addition, even if KNN temporarily described in the present specification has a structure with lower symmetry, there is no particular contradiction.

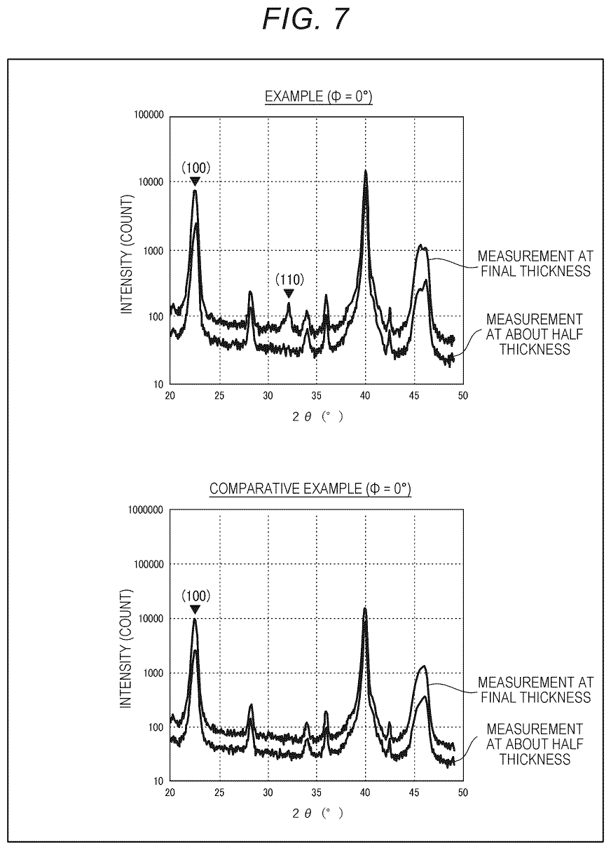

FIG. 7 shows results of XRD measurement of the KNN thin films in Example and Comparative Example under the measurement conditions of φ=0°. The drawings of FIG. 7 show a result of measurement at a thickness about half of a final thickness and a result of measurement at the final thickness. In each graph of FIG. 7, two profiles are displayed side by side in a vertical direction for comparison, and numerical values of a peak intensity on a vertical axis do not always coincide with a peak position of the profile.

In all of the four profiles shown in FIG. 7, a peak caused by the (100) orientation was observed at a position of 2θ=22° to 23°. In the profile measured at the final thickness in Example, a peak caused by the (110) orientation was observed at a position of 2θ=32° to 33°.

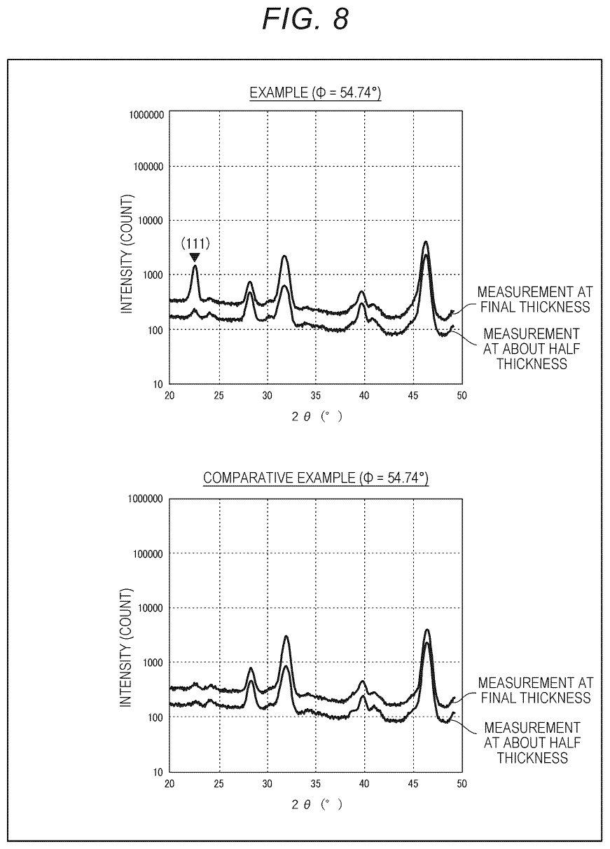

The KNN thin film has a very weak peak intensity caused by the (111) orientation in the XRD measurement at φ=0°. Therefore, the XRD measurement was performed with a state in which the substrate is tilted by 54.74°. FIG. 8 shows results of XRD measurement of the KNN thin films in Example and Comparative Example under measurement conditions of φ=54° and 74°. The drawings of FIG. 8 show a result of measurement at a thickness that is about half of a final thickness and a result of measurement at the final thickness. In FIG. 8, the two profiles are also displayed side by side in the vertical direction for comparison, and the numerical values of the peak intensity on the vertical axis do not always coincide with the peak position of the profile.

In the XRD measurement at φ=54.74°, a diffraction peak derived from (100) of the (111) oriented KNN is observed in a vicinity of 2θ=21° to 24°. This is because an angle formed by the (100) plane and the (111) plane is about 54.74°, and the KNN thin film formed by the spin coating method has the degree of rotation freedom of the crystal orientation in the substrate plane, so that the diffraction peak caused by the (111) orientation is observed without depending on the in-plane orientation of the (111) plane.

As shown in FIG. 8, in the profile measured at the final thickness in Example, a peak caused by the (100) orientation was observed at a position of 2θ=21° to 24°. From this, it was found that in the KNN thin film in Example, the (111)-oriented component exists in a direction perpendicular to the plane.

Table 1 shows a list of peak intensities at the final thickness (total thickness) and about half of the final thickness (half thickness) in Example and Comparative Example. “Intensity ratio” and “all/half” in Table 1 are values calculated by the following formulas.

(Intensity ratio)={I(110)+I(111)}/{I(100)+I(110)+I(111)}

(All/half)={(intensity ratio)total thickness}/{(intensity ratio)half thickness}

It is known that the strain amount required for the characteristics of the piezoelectric element increases in the KNN crystals oriented in the (100) plane. As shown in Table 1, a high peak intensity in the (100) orientation was obtained in the KNN thin film in Example although it was lower than that of Comparative Example, and the KNN thin confirmed to have sufficient piezoelectric film was characteristics. A measurement range of the arithmetic average height (Sa) is a square region whose one side is 1 μm on the KNN thin film. The number of measurement points of the arithmetic average height (Sa) was 5, and an average value of minimum values of the arithmetic average height (Sa) at the measurement points and an average value of maximum values of the arithmetic average height (Sa) at the measurement points were calculated. The arithmetic average height in Example is 0.0032 nm or more and 0.008 nm or less, which is larger than the arithmetic average height in

TABLE 1

| | | | | | | | Arithmetic | Arithmetic |
|---|---|---|---|---|---|---|---|---|
| | | | | | | | average | average |
| | | | | | | | height (Sa) | height (Sa) |
| | | | | | Intensity | Total/ | Minimum | Maximum |
| | Thickness | I (100) | I (110) | I (111) | ratio | half | value (nm) | value (nm) |
| Example | Half thickness | 2353 | 4 | 83 | 0.04 (A) | 4.1 (B/A) | — | — |
| | Total thickness | 3714 | 40 | 601 | 0.15 (B) | | 0.0032 | 0.0080 |
| Comparative | Half thickness | 2623 | 7 | 49 | 0.02 (A) | 0.6 (B/A) | — | — |
| Example | Total thickness | 4866 | 6 | 55 | 0.01 (B) | | 0.0019 | 0.0022 |

### Adhesion Test of Electrode

Table 2 shows the results of electrode adhesion tests performed on Example and Comparative Example. The Pt film formed on the KNN thin film was not peeled off in Example, whereas the Pt film was peeled off in Comparative Example. In Example, there were a large number of (110)-oriented and (111)-oriented crystal grains having large unevenness, and the adhesion of the Pt film was improved by the unevenness. As shown in Table 1, in the KNN thin film in Example, an intensity ratio (B) of the total thickness was four times or more an intensity ratio (A) of the half thickness, and was remarkably larger than that of

TABLE 2

| | Film peeling of electrode |
|---|---|
| Example | No |
| Comparative Example | Yes |

What is claimed is:

1. A piezoelectric element comprising:
a substrate;
a first electrode formed on the substrate;
a thin-film piezoelectric body formed on the first electrode and containing potassium, sodium, and niobium; and
a second electrode formed on the thin-film piezoelectric body, wherein
when the thin-film piezoelectric body is divided into two equal parts in a film formation direction, a first electrode side is defined as a first region, and a second electrode side is defined as a second region,
a value A obtained by dividing a total value of an XRD peak intensity of a (111) plane and an XRD peak intensity of a (011) plane in the first region by a total value of an XRD peak intensity of a (100) plane, the XRD peak intensity of the (111) plane, and the XRD peak intensity of the (011) plane is smaller than a value B obtained by dividing a total value of an XRD peak intensity of a (111) plane and an XRD peak intensity of a (011) plane in the thin-film piezoelectric body by a total value of an XRD peak intensity of a (100) plane, the XRD peak intensity of the (111) plane, and the XRD peak intensity of the (011) plane.

2. The piezoelectric element according to claim 1, wherein
the value B is four times or more the value A.

3. The piezoelectric element according to claim 1, wherein
an arithmetic average height of the thin-film piezoelectric body is 0.0032 nm or more and 0.008 nm or less.

4. A piezoelectric actuator comprising:
a vibration plate;
a first electrode formed on the vibration plate;
a thin-film piezoelectric body formed on the first electrode and containing potassium, sodium, and niobium; and
a second electrode formed on the thin-film piezoelectric body, wherein
when the thin-film piezoelectric body is divided into two equal parts in a film formation direction, a first electrode side is defined as a first region, and a second electrode side is defined as a second region,
a value A obtained by dividing a total value of an XRD peak intensity of a (111) plane and an XRD peak intensity of a (011) plane in the first region by a total value of an XRD peak intensity of a (100) plane, the XRD peak intensity of the (111) plane, and the XRD peak intensity of the (011) plane is smaller than a value B obtained by dividing a total value of an XRD peak intensity of a (111) plane and an XRD peak intensity of a (011) plane in the thin-film piezoelectric body by a total value of an XRD peak intensity of a (100) plane, the XRD peak intensity of the (111) plane, and the XRD peak intensity of the (011) plane.

5. The piezoelectric actuator according to claim 4, wherein
the value B is four times or more the value A.

6. The piezoelectric actuator according to claim 4, wherein
an arithmetic average height of the thin-film piezoelectric body is 0.0032 nm or more and 0.008 nm or less.
